(19) United States
(12) Patent Application Publication
(10) Pub. No.: US 2026/0330085 A1
(43) Pub. Date: Oct. 22, 2026

(54) METHOD AND APPARATUS FOR GENERATING 3D MODEL, COMPUTER-READABLE STORAGE MEDIUM, AND METHOD FOR ASSEMBLING CASING

(71) Applicant: MITSUBISHI HEAVY INDUSTRIES, LTD., Tokyo (JP)

(72) Inventors: Satoshi Kumagai, Tokyo (JP); Shunsuke Mizumi, Tokyo (JP); Koji Ishibashi, Tokyo (JP)

(73) Assignee: MITSUBISHI HEAVY INDUSTRIES, LTD., Tokyo (JP)

(21) Appl. No.: 19/646,755

(22) Filed: Apr. 14, 2026

(30) Foreign Application Priority Data
Apr. 18, 2025 (JP) 2025-069076

(51) Int. Cl. G06F 30/17

(52) U.S. Cl. CPC G06F 30/17

(57) ABSTRACT

Provided is a method for generating a 3D model of a structure in which a pair of components having main bodies and flange parts are bolted together with mounting surfaces of the flange parts in contact with each other, the method including acquiring 3D shape data of the mounting surfaces, and generating 3D models of the flange parts by performing extrusion processing on the mounting surfaces in a thickness direction of the flange parts based on the 3D shape data.

### CROSS-REFERENCE TO RELATED APPLICATIONS

The present application claims priority to and incorporates by reference the entire contents of Japanese Patent Application No. 2025-069076 filed in Japan on April 18, 2025.

### FIELD

The present disclosure relates to a method and apparatus for generating a 3D model, a computer-readable storage medium, and a method for assembling a casing.

### BACKGROUND

A steam turbine as a rotary machine includes a casing, a rotor, a turbine vane, and a turbine blade. In the casing, the rotor is rotatably supported inside, and a plurality of the turbine blades are fixed to the rotor spaced in the axial direction. In the casing, a plurality of the turbine vanes are fixed inside spaced in the axial direction. The turbine vanes and the turbine blades are arranged alternately in the axial direction. The casing includes a lower half and an upper half, which are two divided parts, which are fastened together by a plurality of bolts to form a ring shape.

During inspection of the steam turbine, the bolts are loosened to separate the lower half and the upper half to inspect and repair internal components. Once the components have been inspected and repaired, the components are housed inside the lower half and the upper half, and the two are bolted together and assembled. The casing may undergo inelastic deformation such as creep deformation due to thermal effects during operation. Deformation of the casing makes it difficult to properly assemble the steam turbine. A technique to solve such a problem is described in, for example, Patent Literature 1.

### CITATION LIST

### Patent Literature

Patent Literature 1: Japanese Patent No. 7416674

### SUMMARY

### Technical Problem

In Patent Literature 1, a reference shape model is created based on reference shape data, which is the design data of components constituting a steam turbine. The reference shape model is a model in which the component is divided into a plurality of microelements by meshes. The measured shape data of the component is then acquired, and the reference shape model is modified using the measured shape data. In this case, when the reference shape model is created, it is unfortunately necessary to create analysis meshes, which requires a long time to create the analysis meshes and increases processing costs.

The present disclosure solves the problems described above, and an object thereof is to provide a method and apparatus for generating a 3D model, a computer program, and a method for assembling a casing that simplify the processing.

### Solution to Problem

To achieve the object, a method according to the present disclosure is for generating a 3D model of a structure in which a pair of components having main bodies and flange parts are bolted together with mounting surfaces of the flange parts in contact with each other, and includes: acquiring 3D shape data of the mounting surfaces; and generating 3D models of the flange parts by performing extrusion processing on the mounting surfaces in a thickness direction of the flange parts based on the 3D shape data.

An apparatus according to the present disclosure is for generating a 3D model of a structure in which a pair of components having main bodies and flange parts are bolted together with mounting surfaces of the flange parts in contact with each other, and includes: a 3D data acquisition unit that acquires 3D shape data of the mounting surfaces; and a 3D model generation unit that generates 3D models of the flange parts by performing extrusion processing on the mounting surfaces in a thickness direction of the flange parts based on the 3D shape data.

A computer-readable storage medium according to the present disclosure has stored thereon a program causing a computer serving as an apparatus for generating a 3D model of a structure in which a pair of components having main bodies and flange parts are bolted together with mounting surfaces of the flange parts in contact with each other to execute: acquiring 3D shape data of the mounting surfaces; and generating 3D models of flange parts by performing extrusion processing on the mounting surfaces in a thickness direction of the flange parts based on the 3D shape data.

A method according to the present disclosure is for assembling a casing that assembles a casing by bolting a flange part of a lower half and a flange part of an upper half together, and includes: generating a 3D model of the lower half and a 3D model of the upper half by the above-described method for generating a 3D model; predicting contact surface pressure caused by bolting the flange part of the lower half and the flange part of the upper half together based on the 3D model of the lower half and the 3D model of the upper half; modifying at least either the flange part of the lower half or the flange part of the upper half in accordance with the contact surface pressure; and bolting the flange part of the lower half and the flange part of the upper half together.

### Advantageous Effects of Invention

The method and apparatus for generating a 3D model, the computer-readable storage medium, and the method for assembling a casing of the present disclosure can simplify the processing.

### BRIEF DESCRIPTION OF DRAWINGS

FIG. 1 is a longitudinal sectional view of a steam turbine of a first embodiment.

FIG. 2 is a longitudinal sectional view of a casing in the steam turbine.

FIG. 3 is a block diagram of an apparatus for generating a 3D model of the first embodiment.

FIG. 4 is a flowchart of a method for generating a 3D model of the first embodiment.

FIG. 5 is an illustrative diagram of the method for generating a 3D model.

FIG. 6 is a block diagram of an apparatus for generating a 3D model of a second embodiment.

FIG. 7 is a flowchart of a method for generating a 3D model of the second embodiment.

FIG. 8 is an illustrative diagram of the method for generating a 3D model.

FIG. 9 is a flowchart of a method for generating a 3D model of a third embodiment.

FIG. 10 is a table of an example of information used to set analysis conditions.

FIG. 11 is a flowchart of a method for generating a 3D model of a fourth embodiment.

FIG. 12 is a schematic diagram of 3D shape data by a point group of a flange surface.

FIG. 13 is a schematic diagram of 3D shape data by meshes of the flange surface.

### DESCRIPTION OF EMBODIMENTS

Suitable embodiments of the present disclosure will be described below in detail with reference to the accompanying drawings. Note that the present disclosure is not limited by these embodiments, and when there are a plurality of embodiments, also includes combinations of the embodiments. The components in the embodiments include those that can be readily assumed by those skilled in the art, those that are substantially identical, and those in what is called the range of equivalence.

### First Embodiment

### Steam Turbine

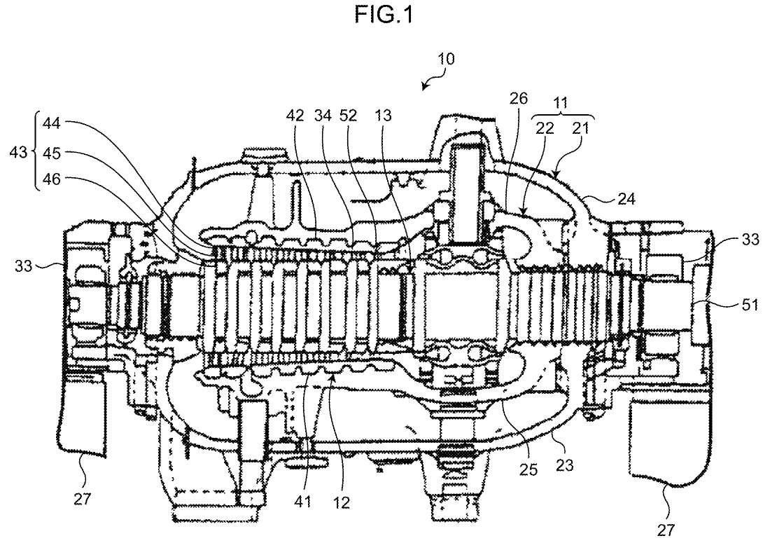

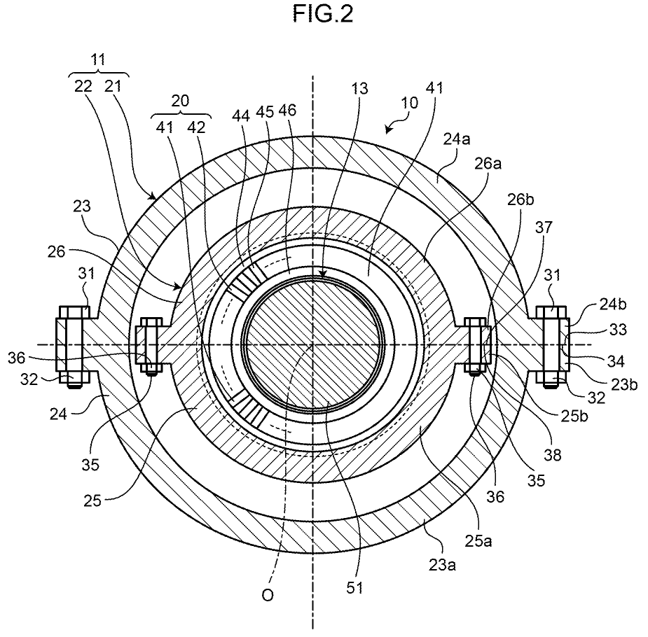

FIG. 1 is a longitudinal sectional view of a steam turbine of a first embodiment, and FIG. 2 is a longitudinal sectional view of a casing in the steam turbine.

As illustrated in FIG. 1 and FIG. 2, this steam turbine 10 includes, as its main components, a casing 11, a stationary body 12, and a rotating body 13.

The casing 11 covers the outer side of the stationary body 12 and the rotating body 13. The casing 11 has a double structure including an outer casing 21 and an inner casing 22. The inner casing 22 is an inner shell covering the surroundings of the stationary body 12 and the rotating body 13, and the outer casing 21 is an outer shell covering the surroundings of the inner casing 22. The outer casing 21 and the inner casing 22 are each an upper and lower two-part structure.

The outer casing 21 has a lower half outer casing 23 of a lower half and an upper half outer casing 24 of an upper half. The inner casing 22 has a lower half inner casing 25 of the lower half and an upper half inner casing 26 of the upper half. In other words, the casing 11 includes the lower half including the lower half outer casing 23 and the lower half inner casing 25, and the upper half including the upper half outer casing 24 and the upper half inner casing 26. Each end of the casing 11 in a turbine axial direction in the lower half outer casing 23 is supported on a base 27.

The lower half outer casing 23 has a main body 23a and a flange part 23b. The upper half outer casing 24 has a main body 24a and a flange part 24b. The lower half outer casing 23 and the upper half outer casing 24 are fastened together by a plurality of bolts 31 and nuts 32 with their flange parts 23b and 24b overlapping and in contact with each other. The flange parts 23b and 24b have flange surfaces 33 and 34, which are contact surfaces facing each other, extending in the horizontal direction.

The lower half inner casing 25 has a main body 25a and a flange part 25b. The upper half inner casing 26 has a main body 26a and a flange part 26b. The lower half inner casing 25 and the upper half inner casing 26 are fastened together by a plurality of bolts 35 and nuts 36 with their flange parts 25b and 26b overlapping and in contact with each other. The flange parts 25b and 26b have flange surfaces 37 and 38, which are contact surfaces facing each other, extending in the horizontal direction.

The stationary body 12 has an upper and lower two-part structure including a lower half 41 and an upper half 42. The lower half 41 and the upper half 42 have their contact surfaces extending in the horizontal direction. In the stationary body 12, the lower half 41 and the upper half 42 are fastened together by bolts and nuts, not illustrated. The stationary body 12 is an annular (tubular) member including a plurality of turbine vane rows 43 spaced in the turbine axial direction and housed in the inner casing 22. Each turbine vane row 43 includes a diaphragm outer ring 44, a plurality of turbine vanes 45, and a diaphragm inner ring 46. The annularly arranged turbine vanes 45 are composed with their outer parts coupled by the diaphragm outer ring 44 and with their inner parts coupled by the diaphragm inner ring 46.

The rotating body 13 is a turbine rotor disposed inside the stationary body 12. The rotating body 13 has a rotor 51 and a plurality of turbine blade rows 52. Each end of the rotor 51 in the axial direction extends outward from the casing 11, and is rotatably supported on the base 27 with a center axis O by a bearing 53. The turbine blade rows 52 include a plurality of turbine blades 54 annularly arranged on the outer part of the rotor 51 and are spaced in the turbine axial direction. The turbine blade rows 52 are arranged alternately with the turbine vane rows 43 in the turbine axial direction.

### Creep Deformation of Casing

For example, the outer casing 21 and the inner casing 22 are provided as casings. The outer casing 21 includes the lower half outer casing 23 and the upper half outer casing 24, and the inner casing 22 includes the lower half inner casing 25 and the upper half inner casing 26. The outer casing 21 is provided with the inner casing 22 inside, and the inner casing 22 houses the stationary body 12 and the rotating body 13 inside.

For example, the outer casing 21 may undergo creep deformation due to thermal effects during operation. During inspection of the steam turbine 10, the upper half outer casing 24 is removed from the lower half outer casing 23. At this time, the lower half outer casing 23 and the upper half outer casing 24 become deformed because they are no longer restrained by the bolts 31. Therefore, after inspection of the steam turbine 10, when the upper half outer casing 24 is assembled to the lower half outer casing 23, unevenness may occur on the flange surfaces 33 and 34, causing steam to leak.

### Apparatus for Generating 3D Model

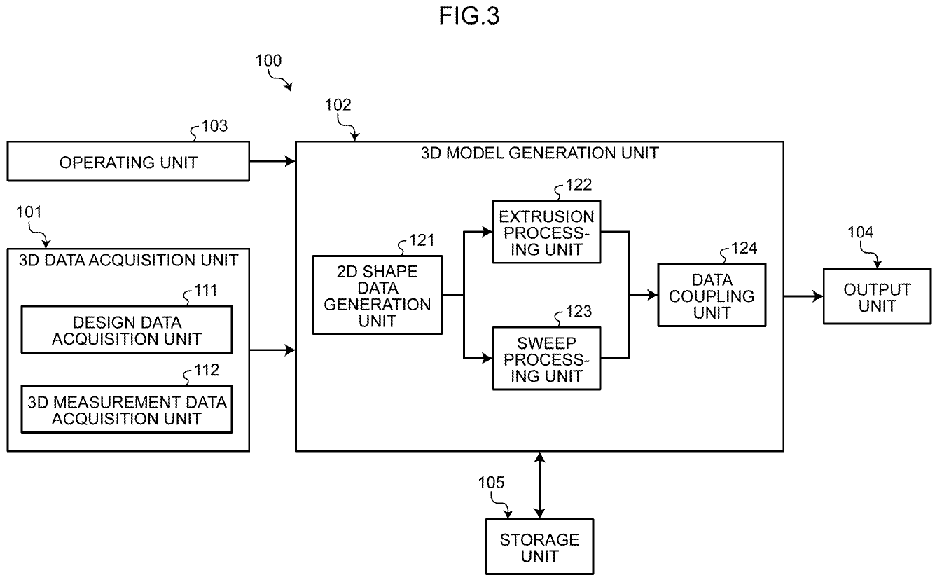

The method and apparatus for generating a 3D model of the first embodiment generate 3D models of the lower half outer casing 23 and the upper half outer casing 24 of the outer casing 21 that have undergone creep deformation due to thermal effects. FIG. 3 is a block diagram of the apparatus for generating a 3D model of the first embodiment.

The apparatus for generating a 3D model of the first embodiment generates a 3D model of a structure in which a pair of components having main bodies and flange parts are bolted together with mounting surfaces of the flange parts in contact with each other. Here, the structure is a casing, which is, for example, the outer casing 21 constituting a turbine casing. The pair of components are the lower half outer casing 23 as the lower half and the upper half outer casing 24 as the upper half. The main bodies are the main bodies 23a and 24a, and the flange parts are the flange parts 23b and 24b. Furthermore, the mounting surfaces are the flange surfaces 33 and 34. However, the structure is a casing, which may be, for example, the inner casing 22 constituting a turbine casing.

As illustrated in FIG. 3, this apparatus 100 for generating a 3D model includes a 3D data acquisition unit 101 and a 3D model generation unit 102. The 3D data acquisition unit 101 acquires 3D shape data of the flange surfaces (mounting surfaces) 33 and 34. The 3D model generation unit 102 generates 3D models of the lower half outer casing 23 and the upper half outer casing 24 based on the 3D shape data of the flange surfaces 33 and 34.

The 3D data acquisition unit 101 has a design data acquisition unit 111 and a 3D measurement data acquisition unit 112.

The design data acquisition unit 111 acquires design data as 3D shape data of the lower half outer casing 23 and the upper half outer casing 24 including the main bodies 23a and 24a and the flange parts 23b and 24b. The 3D measurement data acquisition unit 112 acquires 3D measurement data as the 3D shape data of the flange surfaces 33 and 34 by 3D measuring the flange surfaces 33 and 34 in the lower half outer casing 23 and the upper half outer casing 24 that have been disassembled. The 3D measurement data acquisition unit 112, for example, acquires 3D images of the flange parts 23b and 24b by causing a laser displacement meter to project a slit-shaped laser beam or the like onto the lower half outer casing 23 and upper half outer casing 24 and causing a camera to measure pattern light.

However, the 3D measurement data acquisition unit 112 is not limited to acquiring the 3D images of the flange parts 23b and 24b by this method. For example, the 3D measurement data acquisition unit 112 may acquire the 3D measurement data by directly measuring the flange parts 23b and 24b or acquire the 3D measurement data from photographic images.

The design data of the lower half outer casing 23 and the upper half outer casing 24 acquired by the design data acquisition unit 111 includes the shape dimensions of the main bodies 23a and 24a, the flange parts 23b and 24b, the flange surfaces 33 and 34, and the like. The 3D measurement data of the flange surfaces 33 and 34 obtained by the 3D measurement data acquisition unit 112 includes the inner diameters of the lower half outer casing 23 and the upper half outer casing 24 and the widths of the flange surfaces 33 and 34, the positions and inner diameters of bolt holes through which the bolts 31 are inserted, and the uneven shapes of the flange surfaces 33 and 34.

The 3D model generation unit 102 has a 2D shape data generation unit 121, an extrusion processing unit 122, a sweep processing unit 123, and a data coupling unit 124. The 3D model generation unit 102 is a control device, and the control device is a computer, which is implemented, for example, by various computer programs stored in a storage unit being executed by a central processing unit (CPU), a micro processing unit (MPU), or the like with a RAM as a work area.

The 2D shape data generation unit 121 converts the 3D measurement data of the flange surfaces 33 and 34 acquired by the 3D measurement data acquisition unit 112 into 2D measurement data and generates it. The 3D measurement data of the flange surfaces 33 and 34 acquired by the 3D measurement data acquisition unit 112 includes position coordinates in the vertical direction, a first horizontal direction (the turbine axial direction), and a second horizontal direction (a turbine radial direction). The 2D shape data generation unit 121 deletes the position coordinate in the thickness direction of the flange surfaces 33 and 34, that is, the vertical direction of the flange surfaces 33 and 34, from the 3D measurement data of the flange surfaces 33 and 34 acquired by the 3D measurement data acquisition unit 112 to convert it into 2D shape data including the position coordinates in the first horizontal direction (the turbine axial direction) and the second horizontal direction (the turbine radial direction).

The extrusion processing unit 122 generates 3D models of the flange parts 23b and 24b by performing extrusion processing on the flange surfaces 33 and 34 in the thickness direction of the flange parts 23b and 24b based on the 3D shape data. In other words, the extrusion processing unit 122 generates the 3D models of the flange parts 23b and 24b by performing extrusion processing on the flange surfaces 33 and 34 having the 2D measurement data acquired by the 3D measurement data acquisition unit 112 and converted by the 2D shape data generation unit 121 in the thickness direction of the flange parts 23b and 24b.

The design data acquisition unit 111 has acquired data on the thicknesses of the flange parts 23b and 24b as the design data of the lower half outer casing 23 and the upper half outer casing 24. Thus, the extrusion processing unit 122 generates the 3D models of the flange parts 23b and 24b by performing extrusion processing on the flange surfaces 33 and 34 in the thickness direction of the flange parts 23b and 24b by the thicknesses of the flange parts 23b and 24b.

In other words, the extrusion processing unit 122 generates the 3D model of the flange part 23b by performing extrusion processing on the flange surface 33 by the thickness of the flange part 23b based on the thickness data of the flange part (a first flange part) 23b and the 2D shape data of the flange surface 33. The extrusion processing unit 122 generates the 3D model of the flange part 24b by performing extrusion processing on the flange surface 34 by the thickness of the flange part 24b based on the thickness data of the flange part (a second flange part) 24b and the 2D shape data of the flange surface (a second mounting surface) 34.

The sweep processing unit 123 generates 3D models of the main bodies 23a and 24a by performing sweep processing on inner surface shapes in the flange surfaces 33 and 34 along an arc shape of the main bodies 23a and 24a based on the 3D shape data. In other words, the sweep processing unit 123 generates the 3D models of the main bodies 23a and 24a by performing sweep processing on the inner surface shapes in the flange surfaces 33 and 34 having the 2D measurement data acquired by the 3D measurement data acquisition unit 112 and converted by the 2D shape data generation unit 121 along the arc shape of the main bodies 23a and 24a.

The design data acquisition unit 111 has acquired the thickness data of the main bodies 23a and 24a as the design data of the lower half outer casing 23 and the upper half outer casing 24. Thus, the sweep processing unit 123 generates the 3D models of the main bodies 23a and 24a by performing sweep processing on the inner surface shapes in the flange surfaces 33 and 34 by 180 degrees along the arc shape of the main bodies 23a and 24a over the thickness regions of the main bodies 23a and 24a. Note that when the thicknesses of the main bodies 23a and 24a are set, since the unevenness of the inner surfaces will also appear on the outer surfaces, the axial distribution of the inner diameters of the lower half outer casing 23 and the upper half outer casing 24 may be moving averaged, and the thicknesses may be added to calculate the outer diameters.

In other words, the sweep processing unit 123 generates the 3D model of the main body 23a by performing sweep processing on the inner surface shape in the flange surface 33 along the arc shape of the main body 23a over the thickness region of the main body 23a based on the thickness data of the main body (a first main body) 23a and the 2D shape data of the flange surface 33. The sweep processing unit 123 generates the 3D model of the main body 24a by performing sweep processing on the inner surface shape in the flange surface 34 along the arc shape of the main body 24a over the thickness region of the main body 24a based on the thickness data of the main body (a second main body) 24a and the 2D shape data of the flange surface 34.

The data coupling unit 124 generates the 3D models of the lower half outer casing 23 and the upper half outer casing 24 by performing coupling processing on the 3D models of the main bodies 23a and 24a and the 3D models of the flange parts 23b and 24b. In this case, there are overlapping common parts between the 3D models of the main bodies 23a and 24a and the 3D models of the flange parts 23b and 24b. Thus, with part of the flange surfaces 33 and 34 and part of the inner surfaces, which are the common parts, as positioning positions, the 3D models of the main bodies 23a and 24a and the 3D models of the flange parts 23b and 24b are subjected to coupling processing.

In other words, the data coupling unit 124 generates the 3D model of the lower half outer casing (a first component, the lower half) 23 by performing coupling processing on the 3D model of the main body 23a and the 3D model of the flange part 23b. The data coupling unit 124 generates the 3D model of the upper half outer casing (a second component, the upper half) 24 by performing coupling processing on the 3D model of the main body 24a and the 3D model of the flange part 24b.

To the 3D model generation unit 102, an operating unit 103, an output unit 104, and a storage unit 105 are connected.

The operating unit 103 can be operated by an operator. The operating unit 103 can be operated by the operator to input various command signals to the 3D model generation unit 102. The operating unit 103 is, for example, a keyboard, touch type display, or the like.

The output unit 104 outputs the data and the like processed by the 3D model generation unit 102. The output unit 104 is, for example, a monitor, a printer, or the like.

The storage unit 105 stores therein computer programs for the 3D model generation unit 102 to execute the processing. The storage unit 105 stores therein the data acquired by the 3D data acquisition unit 101, the data generated by the 3D model generation unit 102, and the like.

### Method for Generating 3D Model

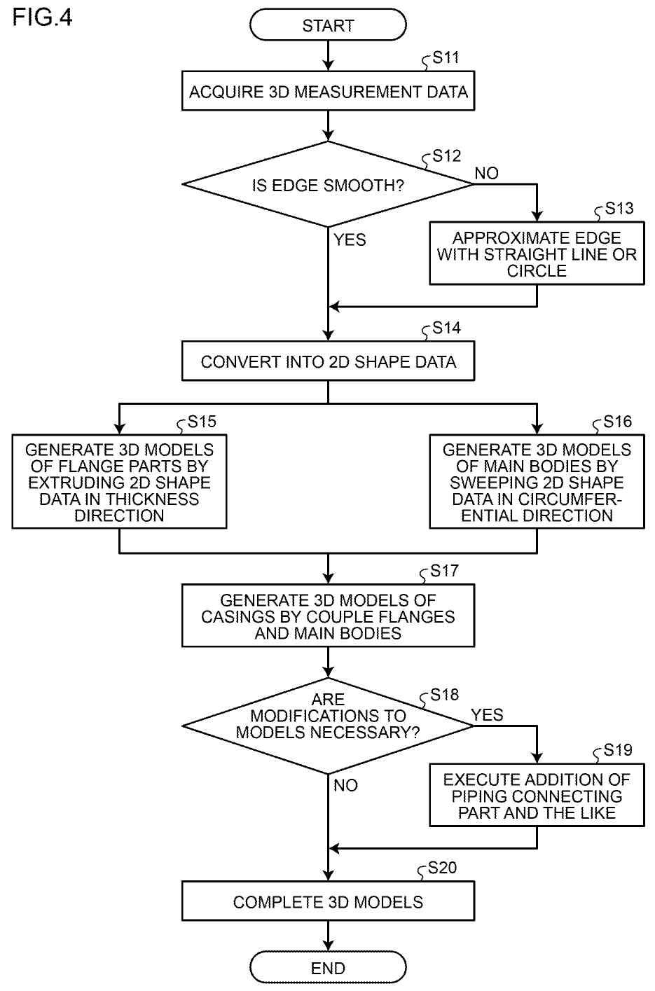

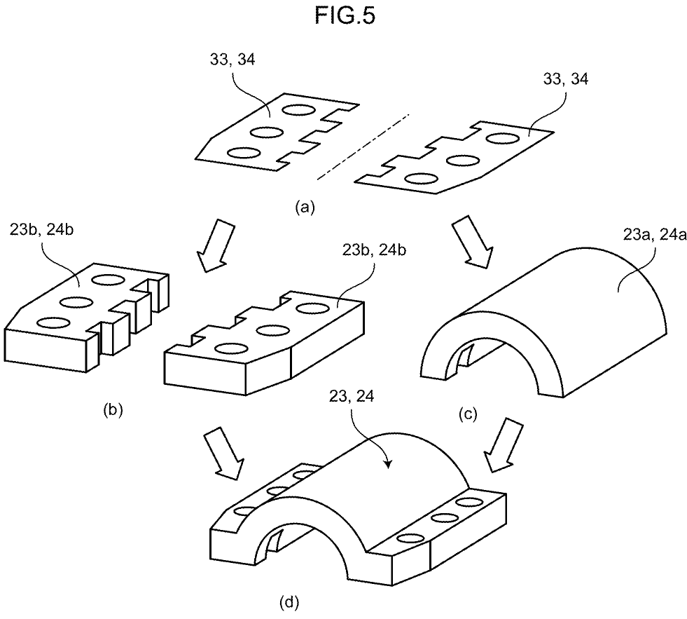

FIG. 4 is a flowchart of a method for generating a 3D model of the first embodiment, and FIG. 5 is an illustrative diagram of the method for generating a 3D model.

As illustrated in FIG. 3 and FIG. 4, at Step S11, the 3D measurement data acquisition unit 112 acquires the 3D measurement data of the flange surfaces 33 and 34 in the lower half outer casing 23 and the upper half outer casing 24 (FIG. 5(a)). At Step S12, the 3D model generation unit 102 determines whether an edge is smooth in the 3D measurement data of the flange surfaces 33 and 34 acquired by the 3D measurement data acquisition unit 112. Determination as to whether the edge is smooth is made, for example, by whether the amount of deviation of a straight line or curve is within a determination value set in advance.

At Step S12, if determining that the edge in the 3D measurement data of the flange surfaces 33 and 34 is smooth (Yes), the 3D model generation unit 102 moves to Step S14. On the other hand, if determining that the edge in the 3D measurement data of the flange surfaces 33 and 34 is not smooth (No), the 3D model generation unit 102 performs processing to approximate the edge in the 3D measurement data of the flange surfaces 33 and 34 to a straight line or curve at Step S13 and then moves to Step S14.

At Step S14, the 2D shape data generation unit 121 converts the 3D measurement data of the flange surfaces 33 and 34 acquired by the 3D measurement data acquisition unit 112 into the 2D measurement data. At Step S15, the extrusion processing unit 122 generates the 3D models of the flange parts 23b and 24b by performing extrusion processing on the flange surfaces 33 and 34 in the thickness direction of the flange parts 23b and 24b based on the 2D shape data (FIG. 5(b)). At this time, the extrusion processing unit 122 uses the thickness data of the flange parts 23b and 24b in the lower half outer casing 23 and the upper half outer casing 24 acquired by the design data acquisition unit 111.

At Step S16, the sweep processing unit 123 generates the 3D models of the main bodies 23a and 24a by performing sweep processing on the inner surface shapes in the flange surfaces 33 and 34 along the arc shape of the main bodies 23a and 24a based on the 2D shape data (FIG. 5(c)). At this time, the sweep processing unit 123 uses the thickness data of the main bodies 23a and 24a in the lower half outer casing 23 and the upper half outer casing 24 acquired by the design data acquisition unit 111.

At Step S17, the data coupling unit 124 generates the 3D models of the lower half outer casing 23 and the upper half outer casing 24 by performing coupling processing on the 3D models of the main bodies 23a and 24a and the 3D models of the flange parts 23b and 24b (FIG. 5(d)). At Step S18, the data coupling unit 124 determines whether modifications to the 3D models of the lower half outer casing 23 and the upper half outer casing 24 that have been generated are necessary. Here, if determining that modifications to the 3D models of the lower half outer casing 23 and the upper half outer casing 24 are not necessary (No), the data coupling unit 124 moves to Step S20. On the other hand, if determining that modifications to the 3D models of the lower half outer casing 23 and the upper half outer casing 24 are necessary (Yes), the data coupling unit 124 executes processing to add a piping connecting part and the like at Step S19, and then moves to Step S20. At Step S20, the 3D models of the lower half outer casing 23 and the upper half outer casing 24 are completed and output to the outside.

### Second Embodiment

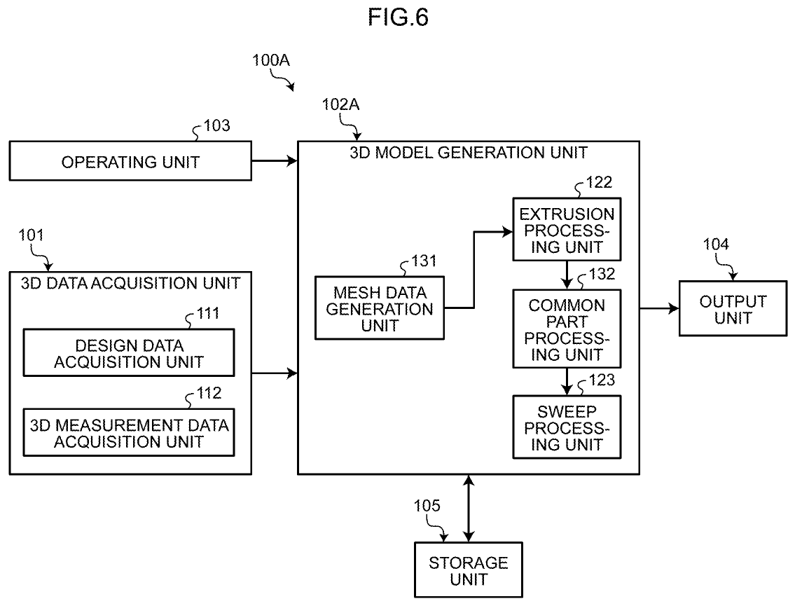

FIG. 6 is a block diagram of an apparatus for generating a 3D model of a second embodiment. Note that components having the same functions as those of the first embodiment described above are denoted by the same symbols, and detailed descriptions thereof will be omitted.

### Apparatus for Generating 3D Model

As illustrated in FIG. 6, this apparatus 100A for generating a 3D model includes the 3D data acquisition unit 101 and a 3D model generation unit 102A. The 3D data acquisition unit 101 acquires the 3D shape data of the flange surfaces 33 and 34. The 3D model generation unit 102A generates the 3D models of the lower half outer casing 23 and the upper half outer casing 24 based on the 3D shape data of the flange surfaces 33 and 34.

The 3D data acquisition unit 101 has the design data acquisition unit 111 and the 3D measurement data acquisition unit 112. The 3D data acquisition unit 101 is the same as that of the first embodiment, and a description thereof will be omitted.

The 3D model generation unit 102A has a mesh data generation unit 131, the extrusion processing unit 122, a common part processing unit 132, and the sweep processing unit 123.

The mesh data generation unit 131 generates mesh data of the flange surfaces 33 and 34 including a plurality of polygons based on the 3D shape data. The apparatus 100 for generating a 3D model of the first embodiment needs to create mesh data after generating the 3D models of the lower half outer casing 23 and the upper half outer casing 24. The apparatus 100A for generating a 3D model of the second embodiment generates mesh data directly based on the 3D shape data of the flange surfaces 33 and 34.

The 3D shape data of the flange surfaces 33 and 34 is point group data, but the mesh data generation unit 131 outputs the point group data as polygon data. The polygon data is data that defines polygonal planes. In other words, the mesh data generation unit 131 connects points that are close to each other among the point group by line segments based on the 3D shape data of the flange surfaces 33 and 34, generates polygons including polygonal planes surrounded by these line segments, for example, triangular planes, and sets analysis meshes including many polygons as one plane. Therefore, the mesh data is a collection of many triangular planar polygons.

The extrusion processing unit 122 generates mesh analysis data in the 3D models of the flange parts 23b and 24b by performing extrusion processing on the mesh data generated by the mesh data generation unit 131 in the thickness direction of the flange parts 23b and 24b.

The design data acquisition unit 111 has acquired data on the thicknesses of the flange parts 23b and 24b as the design data of the lower half outer casing 23 and the upper half outer casing 24. Thus, the extrusion processing unit 122 generates the 3D models of the flange parts 23b and 24b by performing extrusion processing on the mesh data in the thickness direction of the flange parts 23b and 24b by the thicknesses of the flange parts 23b and 24b.

The common part processing unit 132 generates mesh data of the common parts including a plurality of polygons for the common parts between the main bodies 23a and 24a and the flange parts 23b and 24b. In other words, the meshes (polygons) of the flange parts 23b and 24b are along the thickness direction of the flange parts 23b and 24b, while the meshes (polygons) of the main bodies 23a and 24a are along the arc shape of the main bodies 23a and 24a. Thus, the common part processing unit 132 modifies the 3D models (analysis meshes) of the flange parts 23b and 24b generated by the extrusion processing unit 122 to mesh data along the arc shape of the main bodies 23a and 24a only in the common parts.

The sweep processing unit 123 generates the 3D models of the main bodies 23a and 24a by performing sweep processing on the mesh data of the common parts generated by the common part processing unit 132 along the arc shape of the main bodies 23a and 24a.

The design data acquisition unit 111 has acquired the thickness data of the main bodies 23a and 24a as the design data of the lower half outer casing 23 and the upper half outer casing 24. Thus, the sweep processing unit 123 generates the 3D models of the main bodies 23a and 24a by performing sweep processing on the inner surface shapes in the flange surfaces 33 and 34 by 180 degrees along the arc shape of the main bodies 23a and 24a over the thickness regions of the main bodies 23a and 24a.

In the above description, the 3D models including pentahedral meshes of the flange parts 23b and 24b are generated by performing extrusion processing on the mesh data including triangular polygons in the thickness direction of the flange parts 23b and 24b, but this shape is not limiting. For example, the 3D models including pentahedral meshes may be divided into tetrahedral meshes. In addition, a node may be added in the middle of each side of the tetrahedron to make it a quadratic element.

When the lower half outer casing 23 and the upper half outer casing 24 are long in the turbine axial direction and the flange surfaces 33 and 34 have different widths, the flange surfaces 33 and 34 may be divided into a plurality of sections in the turbine axial direction, and extrusion processing may be performed. Furthermore, when the thicknesses of the main bodies 23a and 24a or the flange parts 23b and 24b differ in the turbine axial direction, the dimension may be set for each region in the turbine axial direction by giving dimensional information on the thicknesses of the main bodies 23a and 24a or the thicknesses of the flange parts 23b and 24b in advance.

The 3D model generation unit 102A may also be provided with the 2D shape data generation unit 121 of the first embodiment (refer to FIG. 3) and perform various processing using the 2D shape data.

### Method for Generating 3D Model

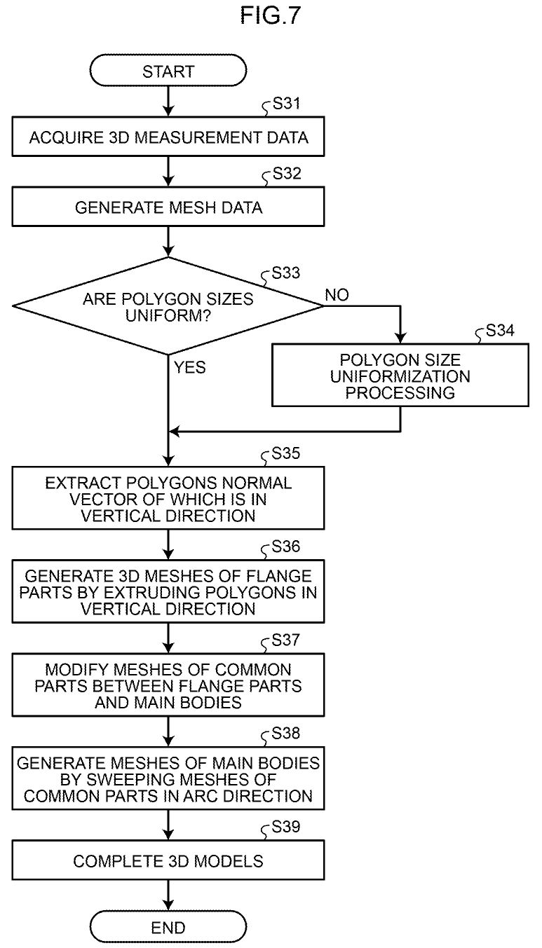

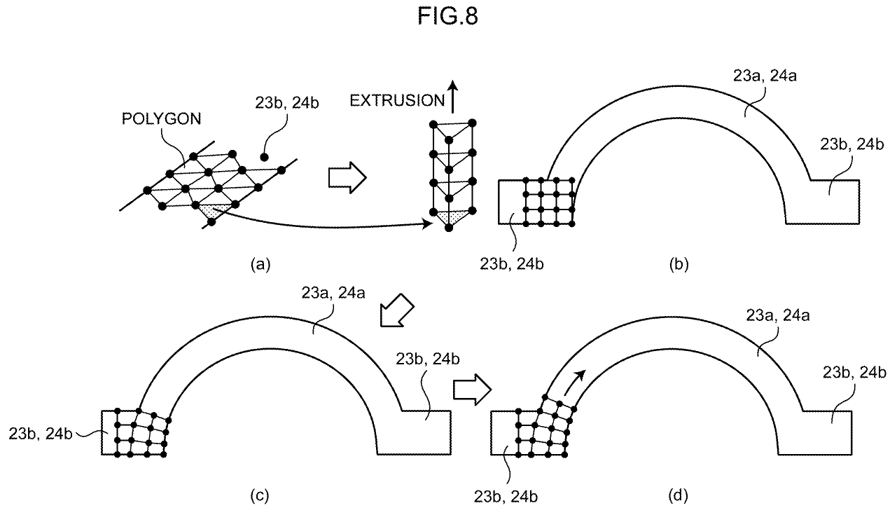

FIG. 7 is a flowchart of a method for generating a 3D model of the second embodiment, and FIG. 8 is an illustrative diagram of the method for generating a 3D model.

As illustrated in FIG. 6 and FIG. 7, at Step S31, the 3D measurement data acquisition unit 112 acquires the 3D measurement data of the flange surfaces 33 and 34 in the lower half outer casing 23 and the upper half outer casing 24. At Step S32, the mesh data generation unit 131 generates the mesh data of the flange surfaces 33 and 34 including a plurality of polygons based on the 3D shape data. At Step S33, the mesh data generation unit 131 determines whether the polygon sizes are uniform in the generated mesh data of the flange surfaces 33 and 34. In other words, as illustrated in FIG. 8(a), the mesh data of the flange surfaces 33 and 34 is generated as, for example, triangular polygonal form data. At Step S33, it is determined whether the polygon sizes of the many triangular polygons are uniform. Note that the determination as to whether the polygon sizes of the many triangular polygons are uniform is made, for example, by whether the amount of deviation of the many polygons is within a determination value set in advance.

Returning back to FIG. 6 and FIG. 7, if determining that the polygon sizes are uniform (Yes) at Step S33, the mesh data generation unit 131 moves to Step S35. On the other hand, if determining that the polygon sizes are not uniform (No), the mesh data generation unit 131 performs polygon size uniformization processing at Step S34, and then moves to Step S35.

At Step S35, the extrusion processing unit 122 extracts polygons the normal vector of which is directed to the vertical direction from the triangular polygons constituting the mesh data. At Step S36, the extrusion processing unit 122 generates the mesh analysis data in the 3D models of the flange parts 23b and 24b by performing extrusion processing on the extracted triangular polygons in the thickness direction of the flange parts 23b and 24b (the vertical direction). In other words, as illustrated in FIG. 8(a) and 8(b), the mesh data of the flange surfaces 33 and 34 includes many triangular polygons, and the 3D models including the meshes in which pentahedra overlap in the thickness direction are generated by performing extrusion processing on the triangular polygons in the thickness direction of the flange parts 23b and 24b.

At Step S37, the common part processing unit 132 generates the mesh data of the common parts including a plurality of polygons for the common parts between the main bodies 23a and 24a and the flange parts 23b and 24b. In other words, as illustrated in FIG. 8(c), the common part processing unit 132 modifies the 3D models (analytical meshes) of the flange parts 23b and 24b generated by the extrusion processing unit 122 to the mesh data along the arc shape of the main bodies 23a and 24a only in the common parts.

At Step S38, the sweep processing unit 123 generates the 3D models of the main bodies 23a and 24a by performing sweep processing on the mesh data of the common parts generated by the common part processing unit 132 along the arc shape of the main bodies 23a and 24a. In other words, as illustrated in FIG. 8(d), the 3D models of the main bodies 23a and 24a are generated by performing sweep processing on the rectangular mesh data along the arc shape of the main bodies 23a and 24a.

After that, at Step S39, the 3D models of the lower half outer casing 23 and the upper half outer casing 24 are completed and output to the outside.

### Third Embodiment

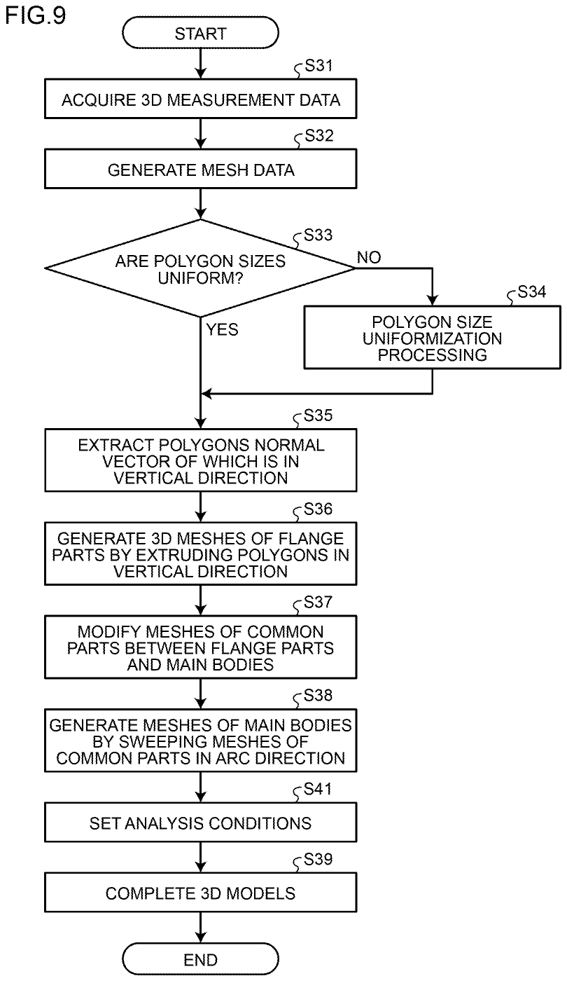

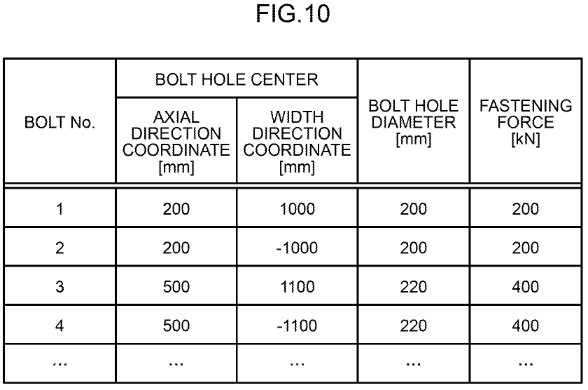

FIG. 9 is a flowchart of a method for generating a 3D model of a third embodiment, and FIG. 10 is a table of an example of information used to set analysis conditions.

The method for generating a 3D model of the second embodiment generates the mesh data based on the 3D shape data of the flange surfaces 33 and 34 and generates the mesh analysis data in the 3D models of the flange parts 23b and 24b by performing extrusion processing on the mesh data in the thickness direction of the flange parts 23b and 24b. The method for generating a 3D model of the third embodiment automatically sets analysis conditions together with the generation of the analysis mesh data in the method for generating a 3D model of the second embodiment.

As illustrated in FIG. 9, the processing from Step S31 to Step S38 is the same as that of the second embodiment, and descriptions thereof will be omitted. At Step S41, the analysis conditions are set.

The work of bolting the lower half outer casing 23 and the upper half outer casing 24 together usually creates models of the bolts 31 and the nuts 32 and loads fastening force. However, depending on the purpose of the analysis, the work can be simplified by applying a pressure equivalent to the fastening force to the seating surfaces of the bolts 31 and the nuts 32. In addition, the work can also be simplified by applying a distributed load equivalent to the fastening force to the edge of the bolt holes.

As illustrated in FIG. 2, the lower half outer casing 23 and the upper half outer casing 24 are provided with a plurality of bolt holes through which the bolts 31 are inserted in the flange parts 23b and 24b spaced in the turbine axial direction. As illustrated in FIG. 9, at Step S41, as the analysis conditions, the pressure of the bolts 31 and the nuts 32 is automatically set based on information on the position of bolt holes, the fastening force, and the like.

The analysis conditions are, for example, as illustrated in FIG. 10, the axial direction coordinates and the width direction coordinate of the bolt hole, the inner diameter of the bolt hole, and the fastening force for the bolts 31. The pressure of the bolts 31 and the nut 32 is automatically set based on information on the position information, the fastening force information, and the like of the bolt holes.

### Fourth Embodiment

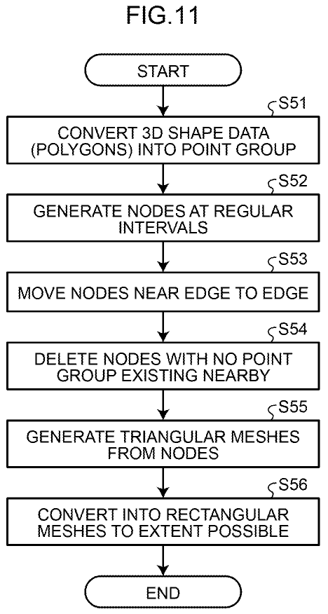

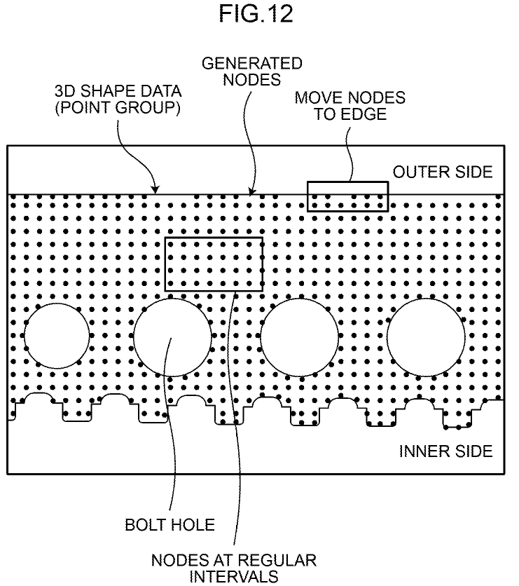

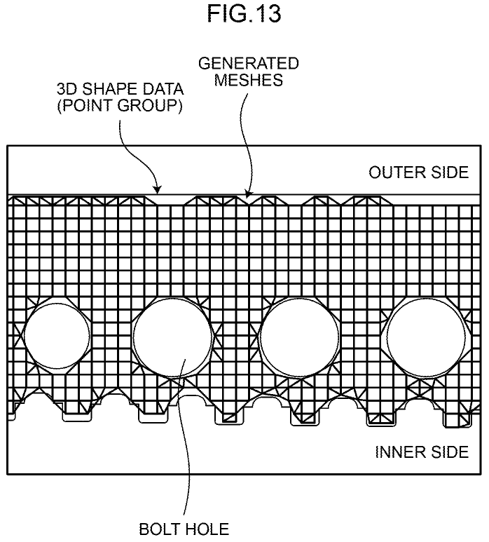

FIG. 11 is a flowchart of a method for generating a 3D model of a fourth embodiment, FIG. 12 is a schematic diagram of 3D shape data by a point group of the flange surface, and FIG. 13 is a schematic diagram of 3D shape data by meshes of the flange surface.

The method for generating a 3D model of the second embodiment generates the 3D models of the flange parts 23b and 24b by performing extrusion processing on the mesh data (polygon data) of the flange surfaces 33 and 34, which is regarded as a plane, in the thickness direction of the flange parts 23b and 24b. In this case, the polygon size may be extremely small in regions with complex shapes, such as near the bolt holes. In this case, the number of elements in the analysis meshes may increase, which may increase the processing time, and the aspect ratio of the elements may increase, which may decrease the accuracy of the analysis.

The method for generating a 3D model of the fourth embodiment automatically generates uniform planar meshes when generating the mesh data (polygon data) of the flange surfaces 33 and 34. This processing is processing by the mesh data generation unit 131 (refer to FIG. 6).

As illustrated in FIG. 11 and FIG. 12, at Step S51, the 3D shape data (polygon data) of the flange surfaces 33 and 34 is converted into a point group. At Step S52, nodes are generated at regular intervals for the point group of the flange surfaces 33 and 34. At Step S53, nodes near the edge of the flange surfaces 33 and 34 are moved to the edge. At Step S54, nodes in regions in which no point group exists nearby (for example, the bolt holes) are deleted.

As illustrated in FIG. 11 and FIG. 13, at Step S55, triangular meshes are generated using a plurality of nodes. At Step S56, the triangular meshes are converted into rectangular meshes to the extent possible. This processing allows meshes with uniform element sizes to be produced. In FIG. 12, the element size is set large so that the processing details can be seen, but in reality, setting the element size small can increase the reproduction accuracy of the bolt holes and the like, and approximates a perfect circle.

### Effects of Present Embodiment

A method for generating a 3D model according to a first aspect is a method for generating a 3D model of the outer casing (structure, casing) 21 in which the lower half outer casing 23 and the upper half outer casing 24 having the main bodies 23a and 24a and the flange parts 23b and 24b (a pair of components) are bolted together with the flange surfaces (mounting surfaces) 33 and 34 of the flange parts 23b and 24b in contact with each other, the method including a step of acquiring 3D shape data of the flange surfaces 33 and 34, and a step of generating 3D models of the flange parts 23b and 24b by performing extrusion processing on the flange surfaces 33 and 34 in a thickness direction of the flange parts 23b and 24b based on the 3D shape data.

The method for generating a 3D model according to the first aspect generates the 3D models of the flange parts 23b and 24b by performing extrusion processing on the flange surfaces 33 and 34 in the thickness direction based on the acquired 3D shape data of the flange surfaces 33 and 34 and can thus simplify the processing. In other words, conventionally, 3D models of structures have been created from design drawings, and analysis meshes have been created from the 3D models, in which this work unfortunately takes a long time and increases costs. On the other hand, the method for generating a 3D model according to the first aspect generates the 3D models of the flange parts 23b and 24b from the acquired 3D shape data of the flange surfaces 33 and 34 and can thus significantly reduce work processes and also reduce costs for analysis compared to conventional methods.

A method for generating a 3D model according to a second aspect is the method for generating a 3D model according to the first aspect, in which the pair of components are the lower half outer casing (the first component) 23 having the main body (the first main body) 23a and the flange part (the first flange part) 23b and the upper half outer casing (the second component) 24 having the main body (the second main body) 24a and the flange part (the second flange part) 24b, and the method includes a step of acquiring 3D shape data of the flange surface (the first mounting surface) 33 of the flange part 23b and the flange surface (the second mounting surface) 34 of the flange part 24b, a step of generating a 3D model of the flange part 23b by performing extrusion processing on the flange surface 33 in a thickness direction of the flange part 23b based on the 3D shape data, and a step of generating a 3D model of the flange part 24b by performing extrusion processing on the flange surface 34 in a thickness direction of the flange part 24b based on the 3D shape data. As a result, the 3D models of the lower half outer casing 23 and the upper half outer casing 24 can be easily created.

A method for generating a 3D model according to a third aspect is the method for generating a 3D model according to the first aspect or the second aspect, in which the 3D shape data has 3D measurement data acquired by 3D measuring the flange surfaces 33 and 34 and design data of the flange parts 23b and 24b, and the 3D models of the flange parts 23b and 24b are generated by performing extrusion processing on shapes of the flange surfaces 33 and 34 obtained from the 3D measurement data in the thickness direction by thicknesses of the flange parts 23b and 24b obtained from the design data. As a result, the 3D models of the flange parts 23b and 24b can be created with high accuracy.

A method for generating a 3D model according to a fourth aspect is the method for generating a 3D model according to any one of the first aspect to the third aspects, in which the 3D models of the flange parts 23b and 24b are generated by generating 2D shape data of the flange surfaces 33 and 34 by deleting shape data in the thickness direction in the flange surfaces 33 and 34 based on the 3D shape data, and performing extrusion processing on the flange surfaces 33 and 34 having the 2D shape data in the thickness direction of the flange parts 23b and 24b. As a result, the processing can be simplified.

A method for generating a 3D model according to a fifth aspect is the method for generating a 3D model according to any one of the first aspect to the fourth aspect, in which the main bodies 23a and 24a have an arc shape, and 3D models of the main bodies 23a and 24a are generated by performing sweep processing on inner surface shapes in the flange surfaces 33 and 34 along the arc shape of the main bodies 23a and 24a based on the 3D shape data. As a result, the 3D models of the main bodies 23a and 24a can be created with high accuracy.

A method for generating a 3D model according to a sixth aspect is the method for generating a 3D model according to the fifth aspect, in which 3D models of the lower half outer casing 23 and the upper half outer casing 24 are generated by performing coupling processing on the 3D models of the flange parts 23b and 24b and the 3D models of the main bodies 23a and 24a. As a result, the 3D models of the lower half outer casing 23 and the upper half outer casing 24 can be easily created.

A method for generating a 3D model according to a seventh aspect is the method for generating a 3D model according to any one of the first aspect to the sixth aspect, in which mesh analysis data in the 3D models of the flange parts 23b and 24b is generated by generating mesh data of the flange surfaces 33 and 34 including a plurality of polygons based on the 3D shape data, and performing extrusion processing on the mesh data in the thickness direction of the flange parts 23b and 24b. As a result, simplified mesh data of the flange parts 23b and 24b can be easily created.

A method for generating a 3D model according to an eighth aspect is the method for generating a 3D model according to the seventh aspect, in which the main bodies 23a and 24a have an arc shape, and 3D models of the main bodies 23a and 24a are generated by generating mesh data of a common part between the flange parts 23b and 24b and the main bodies 23a and 24a, the common part including a plurality of polygons, and performing sweep processing on the mesh data of the common part along the arc shape of the main bodies 23a and 24a. As a result, the 3D models of the lower half outer casing 23 and the upper half outer casing 24 can be easily created.

A method for generating a 3D model according to a ninth aspect is the method for generating a 3D model according to any one of the first aspect to the eighth aspect, in which polygonal mesh data of the flange surfaces 33 and 34 are generated by generating a plurality of nodes at regular intervals in a plurality of polygons based on the 3D shape data, moving nodes near an edge to the edge, deleting nodes in a certain range, and using a plurality of remaining nodes. As a result, when polygon sizes in regions with complex shapes are small and problems arise with the number of elements and aspect ratios, planar meshes with uniform element sizes can be automatically generated from 3D shape data.

A method for generating a 3D model according to a 10th aspect is the method for generating a 3D model according to any one of the first aspect to the ninth aspect, in which the structure is the outer casing 21 as a casing having the lower half outer casing (the lower half) 23 and the upper half outer casing (the upper half) 24, the lower half outer casing 23 has the main body (the lower half main body) 23a having a semicircular arc shape and the flange part (the lower half flange part) 23b, the upper half outer casing 24 has the main body (the upper half main body) 24a having a semicircular arc shape and the flange part (the upper half flange part) 24b, and 3D models of the flange part 23b of the lower half outer casing 23 and the flange part 24b of the upper half outer casing 24 are generated by performing extrusion processing on the flange surfaces 33 and 34 in the flange parts 23b and 24b in the thickness direction. As a result, the 3D models of the flange parts 23b and 24b can be easily created.

An apparatus for generating a 3D model according to an 11th aspect is an apparatus 100 or 100A for generating a 3D model of the outer casing 21 in which the lower half outer casing 23 and the upper half outer casing 24 (a pair of components) having the main bodies 23a and 24a and the flange parts 23b and 24b are bolted together with the flange surfaces (mounting surfaces) 33 and 34 of the flange parts 23b and 24b in contact with each other, the apparatus including the 3D data acquisition unit 101 that acquires 3D shape data of the flange surfaces (mounting surfaces) 33 and 34, and the 3D model generation unit 102 that generates 3D models of the flange parts 23b and 24b by performing extrusion processing on the flange surfaces 33 and 34 in a thickness direction of the flange parts 23b and 24b based on the 3D shape data. As a result, the processing can be simplified.

A computer program according to a 12th aspect causes a computer that is caused to operate as an apparatus 100 or 100A for generating a 3D model, in a method for generating a 3D model of the outer casing 21 in which the lower half outer casing 23 and the upper half outer casing 24 (a pair of components) having the main bodies 23a and 24a and the flange parts 23b and 24b are bolted together with the flange surfaces (mounting surfaces) 33 and 34 of the flange parts 23b and 24b in contact with each other, to execute a step of acquiring 3D shape data of the flange surfaces 33 and 34, and a step of generating 3D models of the flange parts 23b and 24b by performing extrusion processing on the flange surfaces 33 and 34 in a thickness direction of the flange parts 23b and 24b based on the 3D shape data. As a result, the processing can be simplified.

A method for assembling a casing according to a 13th aspect is a method for assembling a casing that assembles the outer casing 21 as a casing by bolting the flange part 23b of the lower half outer casing (the lower half) 23 and the flange part 24b of the upper half outer casing (the upper half) 24 together, the method including a step of generating a 3D model of the lower half outer casing 23 and a 3D model of the upper half outer casing 24 by a method for generating a 3D model, a step of predicting contact surface pressure caused by bolting the flange part of the lower half outer casing 23 and the flange part of the upper half outer casing 24 together based on the 3D model of the lower half outer casing 23 and the 3D model of the upper half outer casing 24, a step of modifying at least either the flange part 23b of the lower half outer casing 23 or the flange part 24b of the upper half outer casing 24 in accordance with the contact surface pressure, and a step of bolting the flange part 23b of the lower half outer casing 23 and the flange part 24b of the upper half outer casing 24 together. As a result, the outer casing 21 can be assembled by properly bolting the lower half outer casing 23 and the upper half outer casing 24 together. When the contact surface pressure of the flange surfaces 33 and 34 in the bolted condition is abnormal, for example, when the contact surface pressure is excessive or insufficient, measures such as modification of the flange surfaces 33 and 34 or replacement of the casing are taken.

In the embodiments described above, the structure is described as the outer casing 21 as a casing, but it may be the inner casing 22. The pair of components having the main bodies and the flange parts are only required to be components to be bolted together with the mounting surfaces of the flange parts in contact with each other and are not limited to the turbine casing.

In the embodiments described above, the 3D models are generated by performing extrusion processing on the mounting surfaces in the thickness direction of the flange parts based on the 3D measurement data, but this configuration is not limiting. The 3D models may be generated by performing extrusion processing on the mounting surfaces in the thickness direction of the flange parts based on the design data.

Furthermore, the method and apparatus for generating a 3D model and the computer program described in the above-described embodiments can be applied to a method for assembling a casing. For example, they can be applied to the method for assembling a turbine described in Japanese Patent No. 7416674, and can be applied in place of the reference shape model creation step (S10) and the modified shape model creation step (S50).

A computer serving as the above-described apparatus 100 or 100A may include at least a processor and a memory, and the above-described computer program may be stored on a (non-transitory) computer-readable storage medium, such as a magnetic disk, an optical disc, or a semiconductor memory, to be read and executed by the computer.

While certain embodiments have been described, these embodiments are not intended to limit the scope of the inventions. The components in the embodiments include ones that a person skilled in the art can easily conceive of, ones that are substantially the same, or ones that fall within their equivalents. Furthermore, various omissions, substitutions, combinations, and changes may be made as appropriate to configurations of the components disclosed in the embodiments without departing from the spirit of the inventions.

### REFERENCE SIGNS LIST

10 Steam turbine
11 Casing
12 Stationary body
13 Rotating body
21 Outer casing (structure, casing)
22 Inner casing
23 Lower half outer casing (first component, lower half)
23a, 24a Main body
23b, 24b Flange part
24 Upper half casing (second component, upper half)
25 Lower half inner casing
26 Upper half inner casing
27 Base
31, 35 Bolt
32, 36 Nut
33, 34, 37, 38 Flange surface
41 Lower half
42 Upper half
43 Turbine vane row
44 Diaphragm outer ring
45 Turbine vane
46 Diaphragm inner ring
51 Rotor
52 Turbine blade row
100, 100A Apparatus for generating 3D model
101 3D data acquisition unit
102, 102A 3D model generation unit
111 Design data acquisition unit
112 3D measurement data acquisition unit
1212D shape data generation unit
122 Extrusion processing unit
123 Sweep processing unit
124 Data coupling unit
131 Mesh data generation unit
132 Common part processing unit

1. A method for generating a 3D model of a structure in which a pair of components having main bodies and flange parts are bolted together with mounting surfaces of the flange parts in contact with each other, the method comprising:
acquiring 3D shape data of the mounting surfaces; and
generating 3D models of the flange parts by performing extrusion processing on the mounting surfaces in a thickness direction of the flange parts based on the 3D shape data.

2. The method for generating a 3D model according to claim 1, wherein
the pair of components are a first component having a first main body and a first flange part and a second component having a second main body and a second flange part, and
the method comprises:
acquiring 3D shape data of a first mounting surface of the first flange part and a second mounting surface of the second flange part;
generating a 3D model of the first flange part by performing extrusion processing on the first mounting surface in a thickness direction of the first flange part based on the 3D shape data; and
generating a 3D model of the second flange part by performing extrusion processing on the second mounting surface in a thickness direction of the second flange part based on the 3D shape data.

3. The method for generating a 3D model according to claim 1, wherein
the 3D shape data has 3D measurement data acquired by 3D measuring the mounting surfaces and design data of the flange parts, and
the 3D models of the flange parts are generated by performing extrusion processing on shapes of the mounting surfaces obtained from the 3D measurement data in the thickness direction by thicknesses of the flange parts obtained from the design data.

4. The method for generating a 3D model according to claim 1, wherein the 3D models of the flange parts are generated by generating 2D shape data of the mounting surfaces by deleting shape data in the thickness direction in the mounting surfaces based on the 3D shape data and performing extrusion processing on the mounting surfaces having the 2D shape data in the thickness direction of the flange parts.

5. The method for generating a 3D model according to claim 1, wherein the main bodies have an arc shape, and 3D models of the main bodies are generated by performing sweep processing on inner surface shapes in the mounting surfaces along the arc shape of the main bodies based on the 3D shape data.

6. The method for generating a 3D model according to claim 5, wherein 3D models of the components are generated by performing coupling processing on the 3D models of the flange parts and the 3D models of the main bodies.

7. The method for generating a 3D model according to claim 1, wherein mesh analysis data in the 3D models of the flange parts is generated by generating mesh data of the mounting surfaces including a plurality of polygons based on the 3D shape data, and performing extrusion processing on the mesh data in the thickness direction of the flange parts.

8. The method for generating a 3D model according to claim 7, wherein the main bodies have an arc shape, and 3D models of the main bodies are generated by generating mesh data of a common part between the flange parts and the main bodies, the common part including a plurality of polygons, and performing sweep processing on the mesh data of the common part along the arc shape of the main bodies.

9. The method for generating a 3D model according to claim 1, wherein polygonal mesh data of the mounting surfaces are generated by generating a plurality of nodes at regular intervals in a plurality of polygons based on the 3D shape data, moving nodes near an edge to the edge, deleting nodes in a certain range, and using a plurality of remaining nodes.

10. The method for generating a 3D model according to claim 1, wherein the structure is a casing having a lower half and an upper half, the lower half has a lower half main body having a semicircular arc shape and a lower half flange part as the flange part, the upper half has an upper half main body having a semicircular arc shape and an upper half flange part as the flange part, and 3D models of the lower half flange part and the upper half flange part are generated by performing extrusion processing on a mounting surface in the lower half flange part and a mounting surface in the upper half flange part in the thickness direction.

11. An apparatus for generating a 3D model of a structure in which a pair of components having main bodies and flange parts are bolted together with mounting surfaces of the flange parts in contact with each other, the apparatus comprising:
a 3D data acquisition unit that acquires 3D shape data of the mounting surfaces; and
a 3D model generation unit that generates 3D models of the flange parts by performing extrusion processing on the mounting surfaces in a thickness direction of the flange parts based on the 3D shape data.

12. A computer-readable storage medium having stored thereon a program causing a computer serving as an apparatus for generating a 3D model of a structure in which a pair of components having main bodies and flange parts are bolted together with mounting surfaces of the flange parts in contact with each other to execute:
acquiring 3D shape data of the mounting surfaces; and
generating 3D models of flange parts by performing extrusion processing on the mounting surfaces in a thickness direction of the flange parts based on the 3D shape data.

13. A method for assembling a casing that assembles a casing by bolting a flange part of a lower half and a flange part of an upper half together, the method comprising:
generating a 3D model of the lower half and a 3D model of the upper half by the method for generating a 3D model according to claim 1;
predicting contact surface pressure caused by bolting the flange part of the lower half and the flange part of the upper half together based on the 3D model of the lower half and the 3D model of the upper half;
modifying at least either the flange part of the lower half or the flange part of the upper half in accordance with the contact surface pressure; and
bolting the flange part of the lower half and the flange part of the upper half together.
